(19) United States
(12) Patent Application Publication
(10) Pub. No.: US 2026/0033206 A1
(43) Pub. Date: Jan. 29, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: Soo Dong KIM, Yongin-si (KR); Rae Young KIM, Yongin-si (KR); Jung Hwan YI, Yongin-si (KR); Jong Beom HONG, Yongin-si (KR)

(21) Appl. No.: 19/200,336

(22) Filed: May 6, 2025

(30) Foreign Application Priority Data
Jul. 26, 2024 (KR) 10-2024-0099553

(51) Int. Cl. H10K 59/38; H10K 59/12; H10K 59/122; H10K 59/80

(52) U.S. Cl. CPC H10K 59/38; H10K 59/1201; H10K 59/122; H10K 59/878

(57) ABSTRACT

A display device includes a pixel defining layer defining a light-emitting region, a light-emitting portion formed within the light-emitting region, a bank on the pixel defining layer to define a color conversion region that covers the light-emitting region in a plan view and forms a pixel region together with the light-emitting region, a color conversion layer in the color conversion region, and a reflective layer on a peripheral portion of a top surface of the color conversion layer. A spacing distance between boundaries of the color conversion region and the light-emitting region is variably formed. A separation distance between boundaries of the reflective layer and the light-emitting region is variably formed.

### CROSS-REFERENCE TO RELATED APPLICATION

The present application claims priority to and the benefit of Korean Patent Application No. 10-2024-0099553, filed on Jul. 26, 2024, in the Korean Intellectual Property Office, the entire disclosure of which is incorporated herein by reference.

### BACKGROUND

### 1. Field

Aspects of some embodiments relate to a display device, a method of manufacturing the same and an electronic device including the same.

### 2. Description of the Related Art

Organic light-emitting devices have a self-luminous property, and may have relatively improved viewing angles and contrast properties. Additionally, organic light-emitting devices may have a high response speed and a relatively high luminance. Display devices have a plurality of pixels. The plurality of pixels may emit light of different colors, and the pixels may include a color control unit including, for example, a quantum dot to relatively improve a color purity.

Accordingly, a light of a first color generated from a light-emitting portion of the pixel can be converted into a light of the second color while passing through the color control unit to be emitted to an outside.

The above information disclosed in this Background section is only for enhancement of understanding of the background and therefore the information discussed in this Background section does not necessarily constitute prior art.

### SUMMARY

Aspects of some embodiments relate to a display device, a method of manufacturing the same and an electronic device including the same. For example, aspects of some embodiments relate to a display device including a light-emitting layer and a color control layer, a method of manufacturing the same and an electronic device including the same.

According to an aspect of the present disclosure, there is provided a display device having relatively improved light emitting efficiency, color purity and luminance. According to an aspect of the present disclosure, there is provided a method

of manufacturing a display device having relatively improved light emitting efficiency, color purity and luminance.

According to an aspect of the present disclosure, there is provided an electronic device including a display device having relatively improved light emitting efficiency, color purity and luminance.

A display device includes a pixel defining layer defining a light-emitting region, a light-emitting portion formed within the light-emitting region, a bank on the pixel defining layer to define a color conversion region that covers the light-emitting region in a plan view and forms a pixel region together with the light-emitting region, a color conversion layer formed within the color conversion region, and a reflective layer on a peripheral portion of a top surface of the color conversion layer. A peripheral portion of the pixel region comprises a first portion having a first spacing distance between boundaries of the color conversion region and the light-emitting region in the plan view; and a second portion having a second spacing distance between boundaries of the color conversion region and the light-emitting region, and the second spacing distance is greater than the first spacing distance. A second separation distance in the plan view between boundaries of the reflective layer and the light-emitting region at the second portion is greater than or equal to a first separation distance in the plan view between boundaries of the reflective layer and the light-emitting region at the first portion.

According to some embodiments, the reflective layer may include a first reflective portion formed on a sidewall of the bank and a second reflective portion arranged on the peripheral portion of the top surface of the color conversion layer. The first separation distance and the second separation distance are distances between an edge of the second reflective portion and the boundary of the light-emitting region.

According to some embodiments, the display device may further include a shielding layer on the second reflective portion to completely cover a top surface of the second reflective portion in a thickness direction. The shielding layer may include a colorant material.

According to some embodiments, the reflective layer may further include a third reflective portion arranged on a top surface of the bank. The shielding layer may commonly cover top surfaces of the second reflective portion and the third reflective portion.

According to some embodiments, the shielding layer may be in contact with the top surface of the second reflective portion.

According to some embodiments, the display device may further include a light-shielding portion arranged on the bank, and a color filter at least partially defined by the light-shielding portion to overlap the color conversion layer in the thickness direction. The shielding layer may be spaced apart from the second reflective portion in the thickness direction and is between the second reflective portion and the light-shielding portion.

According to some embodiments, the display device may further include a lower substrate on which the pixel defining layer and the light-emitting portion are arranged, an upper substrate, a color filter arranged on a bottom surface of the upper substrate, and a light-shielding portion at least partially defining a side of the color filter. The light-shielding portion may include a first light-shielding portion and a second light-shielding portion that are sequentially stacked from the bottom surface of the upper substrate.

According to some embodiments, the first light-shielding portion may protrude from the second light-shielding portion and may completely cover the second reflective portion in the thickness direction.

According to some embodiments, the display device may further include a non-colored shielding layer that completely covers a top surface of the second reflective portion.

According to some embodiments, the non-colored shielding layer may include molybdenum (Mo) or an oxide thereof.

According to some embodiments, the display device may further include a capping layer arranged between of the second reflective portion and the top surface of the color conversion layer.

According to some embodiments, the capping layer may be provided as a low-refractive layer having a refractive index difference of 0.1 or more from the color conversion layer.

According to some embodiments, the first reflective portion may be in contact with sidewalls of the bank and the color conversion layer.

According to some embodiments, the second separation distance may be greater than the first separation distance.

According to some embodiments, the first spacing distance may be in a range from 4 μm to 6 μm, the second spacing distance may be in a range from 10 μm to 20 μm, the first separation distance may be in a range from 2 μm to 3 μm, and the second separation distance may be in a range from 3 μm to 6 μm.

According to some embodiments, the boundary of the reflective layer may be located between the boundary of the color conversion region and the boundary of the light-emitting region in the plan view.

A display device includes a pixel defining layer defining a light-emitting region, a light-emitting portion formed within the light-emitting region, a bank on the pixel defining layer to define a color conversion region that covers the light-emitting region in a plan view and forms a pixel region together with the light-emitting region, a color conversion layer formed within the color conversion region, and a reflective layer on a peripheral portion of a top surface of the color conversion layer. The pixel region has a major axis side and a minor axis side, and a separation distance between boundaries of the reflective layer and the light-emitting region in a minor axis direction at the major axis side is greater than a separation distance between boundaries of the reflective layer and the light-emitting region in a major axis direction at the minor axis side.

According to some embodiments, a spacing distance between the color conversion region and the light-emitting region in the plan view may be constant throughout the pixel region.

In a method of manufacturing a display device, a color filter is formed on an upper substrate. A capping layer is formed on the color filter. A bank that forms a first opening is formed on the capping layer. A reflective layer in contact with a surface of the bank and a bottom surface of the first opening is formed. A portion of the reflective layer formed on the bottom surface of the first opening is partially etched to form a reflective portion including an edge portion formed on a periphery of the bottom surface of the first opening. A color conversion layer filling the first opening is formed on the reflective portion and the capping layer to form an upper structure including the upper substrate, the color filter and the color conversion layer. The upper structure is laminated with a lower structure including a light-emitting portion and a lower substrate.

According to some embodiments, in the formation of the reflective portion, a distance between the edge portion and a sidewall of the bank is variably formed.

In a display device according to some embodiments of the present invention, spacing distance/separation distance of a reflective layer partially covering a top surface of a color conversion layer may be adjusted. Accordingly, a light recycling may be sufficiently induced while maintaining an aperture ratio of a pixel.

According to some embodiments, a shielding layer covering the reflective layer may be formed to relatively reduce a light reflection while increasing a light efficiency.

An electronic device includes the above-described the display device, a housing supporting the display device, and a window structure providing a screen of the display device.

According to some embodiments, the electronic device may include a flat

panel display, a curved display, a computer monitor, a medical monitor, a television, a billboard, an indoor or outdoor lighting, a signal light, a head-up display, a transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a virtual or augmented reality display, a vehicle, a video wall, a theater or stadium screen, or a phototherapy device.

### BRIEF DESCRIPTION OF THE DRAWINGS

FIG. 1 is a schematic exploded perspective view illustrating a display device according to some embodiments.

FIG. 2 is a schematic cross-sectional view illustrating a display panel according to some embodiments.

FIG. 3 is a schematic plan view illustrating a display panel according to some embodiments.

FIG. 4 is a plan view illustrating a pixel arrangement of a display device according to some embodiments.

FIG. 5 is a cross-sectional view taken along a line I-I′ of FIG. 4 in a thickness direction.

FIGS. 6A and 6B are schematic cross-sectional views illustrating a light-emitting device according to some embodiments.

FIG. 7 is a cross-sectional view taken along a line II-II′ of FIG. 4 in the thickness direction.

FIGS. 8 to 10 are schematic cross-sectional views illustrating display devices according to some embodiments.

FIG. 11 is a schematic cross-sectional view illustrating a display device according to some embodiments.

FIG. 12 is a plan view illustrating a pixel arrangement of a display device

according to some embodiments.

FIG. 13 is a cross-sectional view taken along a line III-III′ of FIG. 12 in a thickness direction.

FIGS. 14 to 19 are schematic cross-sectional views for describing a method of manufacturing a display device according to some embodiments.

FIGS. 20 to 23 are schematic cross-sectional views for describing a method of manufacturing a display device according to some embodiments.

FIG. 24 is a plan view illustrating a pixel arrangement of a display device according to some embodiments.

### DETAILED DESCRIPTION

Hereinafter, aspects of some embodiments of the present invention will be described in more detail with reference to the attached drawings. The same reference numerals can I be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms “on”, “connected”, “coupled,” etc., used herein refers to a direct placement/connection/combination, and also refers to a case where another element is interposed two different elements.

The terms such as “first”, “second”, “below”, “below”, “above,” “above,” etc., are used in a relative sense to distinguish different elements or positions, and do not specify an absolute position or an absolute order.

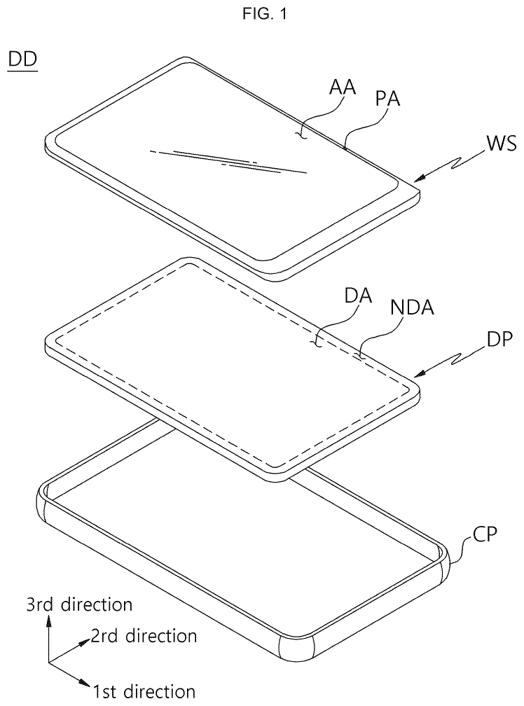

FIG. 1 is a schematic exploded perspective view illustrating a display device according to some embodiments.

Referring to FIG. 1, a display device DD may include a window structure WS, a display panel DP, and a cover panel CP. The display device DD may include a liquid crystal display (LCD) device, an organic light emitting diode (OLED) display device, a quantum dot light emitting diode (QLED) display device, etc.

In FIG. 1, a first direction and a second direction may refer to two directions parallel to a display surface of the window structure WS and/or the display panel DP, and perpendicular to each other. For example, the first direction may correspond to an X-direction (a row direction) of the display device DD or the display panel DP, and the second direction may correspond to a Y-direction (a column direction) of the display device DD or the display panel DP.

The third direction may be perpendicular to the first direction and the second direction. The third direction may correspond to a Z-direction (a thickness direction) of the display device DD or the display panel DP.

In the accompanying figures, the definitions of the direction described above may be commonly applied.

The cover panel CP, the display panel DP and the window structure WS may be sequentially stacked in the third direction.

The window structure WS may provide an external display surface recognized by a user of the display device DD, and may include a transparent material film. For example, the window structure WS may include glass (e.g., ultra-thin glass UTG), a hard coating film, a plastic film, etc.

An outer surface of the window structure WS may include an active area AA and a peripheral area PA. The active area AA may provide a surface form which an image of the display device DD is displayed, and to which the user's touch/instruction is input. The peripheral area PA may correspond (or substantially correspond) to a bezel area of the display device DD.

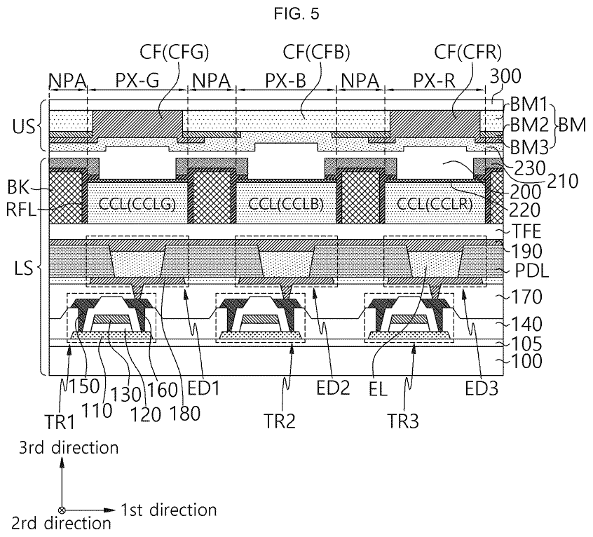

According to some embodiments, an upper substrate 300 (see FIG. 5) may serve as a window structure WS.

The display panel DP may include a display area DA and a non-display area NDA. The display area DA of the display panel DP may correspond (or substantially correspond) to or overlap the active area AA of the window structure WS. The non-display area NDA of the display panel DP may correspond (or substantially correspond) to or overlap the peripheral area PA of the window structure WS. According to some embodiments, the non-display area NDA may surround (e.g., in a periphery or outside a footprint of) the display area DA.

The cover panel CP may serve as a rear panel or a rear housing of the display device DD. The cover panel CP may include a plate (e.g., an SUS plate) that may support the display panel DP, a circuit board (e.g., a printed circuit board (PCB)), etc. The cover panel CP may include an elastic material for absorbing shock of the display device DD.

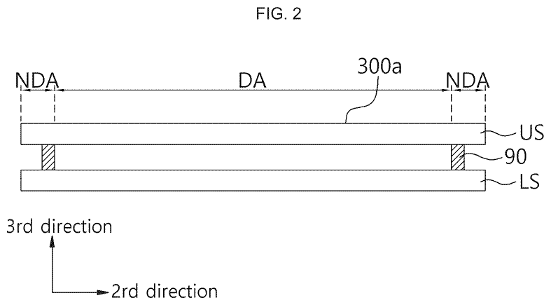

FIG. 2 is a schematic cross-sectional view illustrating a display panel according to some embodiments.

Referring to FIG. 2, the display panel DP or the display device DD may include an upper structure US and a lower structure LS. As will be described later with reference to FIG. 5, the upper structure US may include the upper substrate 300 and a color control structure located on the upper substrate 300. The lower structure LS may include a lower substrate 100 and a light-emitting device located on the lower substrate 100.

According to some embodiments, the upper structure US and the lower structure LS may be coupled or laminated to each other by a sealant 90. An active surface or a display surface of the display device DD or the display panel DP may be provided by an outer surface 300a of the upper substrate 300 (e.g., an upper surface of the upper substrate 300).

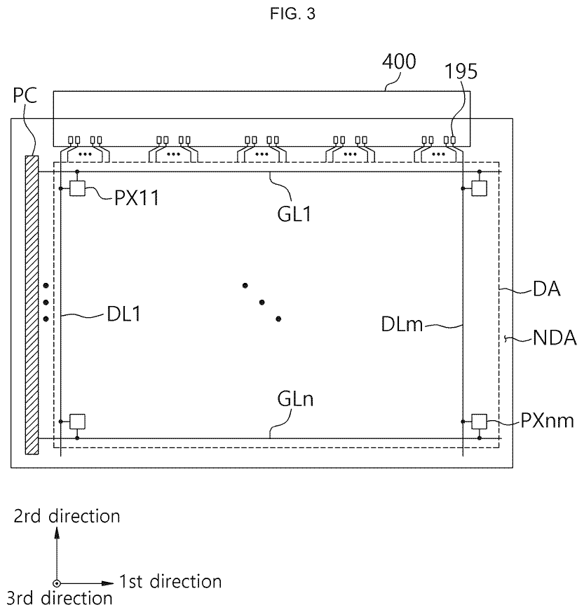

FIG. 3 is a schematic plan view illustrating a display panel according to some embodiments.

Referring to FIG. 3, a plurality of pixels PX11 to PXnm may be arranged in the display area DA of the display panel DP.

According to some embodiments, a pixel circuit including gate lines GL1 to GLn forming first to n^{th} rows and data lines DL1 to DLm forming first to m^{th} columns may be included in the lower structure LS of the display panel DP. Each of the pixels PX11 to PXnm may be connected to a corresponding an n^{th}-row gate line among a plurality of the gate lines GL1 to GLn and a corresponding an m^{th}-row data line among a plurality of data lines DL1 to DLm.

Each of the pixels PX11 to PXnm may further include a pixel driving circuit including a transistor and the light-emitting device as described below. According to some embodiments, the pixel circuit may further include wirings such as a power line and a ground line.

FIG. 3 illustrates that the data lines DL1 to DLm extend in the second direction and the gate lines GL1 to GLn extend in the first direction, but the extending direction are not limited thereto.

A peripheral circuit PC may be located in the peripheral area PA of the display device DD or the non-display area NDA of the display panel DP. For example, the peripheral circuit PC may include a gate driving circuit. The gate driving circuit may be integrated into the display panel DP through an oxide silicon gate (OSG) driver circuit process or an amorphous silicon gate (ASG) driver circuit process.

The display device DD may further include a printed circuit board 400. Pads 195 of the pixel circuit may be assembled at one side portion of the non-display area NDA. The printed circuit board 400 may be electrically connected to the pixel circuit through the pads 195. For example, the printed circuit board 400 may be electrically connected to the pads 195 through a heating-compression process using a conductive intermediate structure such as an anisotropic conductive film ACF.

An integrated circuit (IC) such as a data driving circuit may be located on the printed circuit board 400. According to some embodiments, an integrated circuit (IC) chip in the form of a chip-on-film COF may be mounted on the printed circuit board 400.

In FIG. 3, a shape of each pixel PX11 to PXnm is illustrated as a square shape for convenience of illustration, but the pixel shape is not limited thereto.

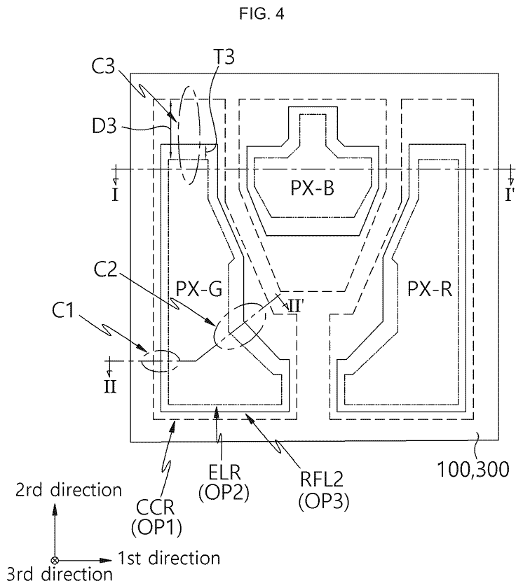

According to some embodiments, the shape of each pixel may be modified as described with reference to FIG. 4 below.

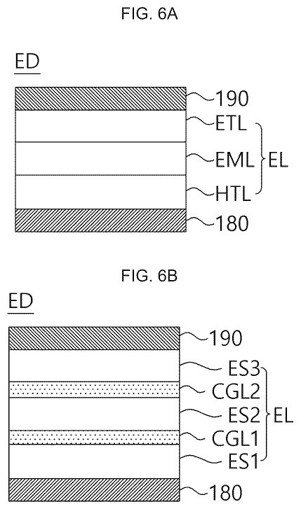

FIG. 4 is a plan view illustrating a pixel arrangement of a display device according to some embodiments. FIG. 5 is a cross-sectional view taken along line a I-I′ of FIG. 4 in a thickness direction. FIGS. 6A and 6B are schematic cross-sectional views illustrating a light-emitting device according to some embodiments.

Referring to FIGS. 4 and 5, pixels of the display device DD may include a first pixel PX-G, a second pixel PX-B and a third pixel PX-R. The first to third pixels PX-G, PX-B and PX-R may be pixels corresponding to different colors.

According to some embodiments, the first pixel PX-G may be a region emitting a green light. For example, the first pixel PX-G may be a region emitting a green light having a central wavelength in a range from 500 nm to 580 nm. The second pixel PX-B may be a region emitting a blue light. For example, the second pixel PX-B may be a region emitting a blue light having a central wavelength in a range from 420 nm to 480 nm. The third pixel PX-R may be a region emitting a red light. For example, the third pixel PX-R may be a region emitting a red light having a central wavelength in a range from 600 nm to 670 nm.

As illustrated in FIG. 4, the first pixel PX-G and the third pixel PX-R may be arranged in a symmetrical shape (or substantially symmetrical shape). Each of the first pixel PX-G and the third pixel PX-R may include one end portion having a relatively small width (a width in the first direction) and the other end portion having a relatively large width.

The second pixel PX-B may be located between the one end portions of the first pixel PX-G and the third pixel PX-R. A length of each of the first and third pixels PX-G and PX-R (a length in the second direction) may be greater than that of the second pixel PX-B.

A pixel group may be defined by the first pixel PX-G, the second pixel PX-B, and the third pixel PX-R as illustrated in FIG. 4. The pixel groups may be repeatedly arranged along the first direction and the second direction. For example, the pixel groups may be repeatedly arranged along the second direction, and the first pixel PX-G, the second pixel PX-B, and the third pixel PX-R may be alternately and repeatedly arranged along the first direction.

Accordingly, each of the first pixels PX-G, the second pixels PX-B, and the third pixels PX-R may form a stripe structure.

As described above, the upper structure US and the lower structure LS may be combined to form the display panel DP. According to some embodiments as illustrated in FIG. 5, the lower structure LS may include transistors TR1, TR2 and TR3, a light-emitting portion EL and a color conversion layer CCL. The upper structure US may include a color filter CF.

The lower structure LS may include a lower substrate 100, the transistors TR1, TR2 and TR3 arranged on the lower substrate 100, and light-emitting devices connected to the transistors TR1, TR2 and TR3.

The lower substrate 100 may serve as a base substrate of the display device DD or the display panel DP, or a back-plane substrate. The lower substrate 100 may include a glass substrate, a ceramic substrate, or a plastic substrate. According to some embodiments, the lower substrate 100 may include a polymer material having transparency and a flexibility (e.g., a set or predetermined flexibility). In this case, the lower substrate 100 may be used in a transparent flexible, bendable or foldable display device.

For example, the lower substrate 100 may include a polymer material such as polyimide, polysiloxane, an epoxy-based resin, an acrylic resin, polyester, polyarylate, polycarbonate, polyethersulfone, polyphenylene sulfide, etc. According to some embodiments, the lower substrate 100 may include polyimide.

A buffer layer 105 may be formed on a top surface of the lower substrate 100. Moisture penetrating through the lower substrate 100 may be blocked by the buffer layer 105, and diffusion of impurities between structures formed on the lower substrate 100 and the lower substrate 100 may be blocked. The buffer layer 105 may be formed entirely over the pixel area (area indicated as PX-G, PX-B, and PX-R in FIG. 5) and a non-pixel area NPA of the lower substrate 100 and may entirely cover the top surface of the lower substrate 100.

The buffer layer 105 may include, e.g., an inorganic insulating material such as silicon oxide, silicon nitride or silicon oxynitride. These may be used alone or in combination of two or more therefrom. According to some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, an atomic layer deposition (ALD) process, etc., to include the inorganic insulating material.

The transistors TR1, TR2, and TR3 may be located on the buffer layer 105. The first transistor TR1, the second transistor TR2 and the third transistor TR3 may be electrically connected to a first light-emitting device ED1, a second light-emitting device ED2 and a third light-emitting device ED3, respectively.

Each of the transistors TR1, TR2 and TR3 may include an active layer 110, a gate insulation layer 120, a gate electrode 130, and connection electrodes 150 and 160. The transistors TR1, TR2 and TR3 may be electrically connected to the light emitting devices of the first pixel PX-G, the second pixel PX-B and the third pixel PX-R, respectively.

The active layer 110 may be located on the buffer layer 105, and may be patterned by, e.g., a photo-lithography process to be repeatedly/regularly arranged at each pixel. The active layer 110 may include a silicon compound such as polysilicon. A p-type dopant or an n-type dopant may be doped in a partial region of the active layer 110, and may include a source region, a drain region and a channel region.

The active layer 110 may include an oxide semiconductor such as indium gallium zinc oxide (IGZO), zinc tin oxide (ZTO), ITZO, etc.

The gate insulation layer 120 may be formed on the active layer 110, and the gate electrode 130 may be stacked on the gate insulation layer 120. As illustrated in FIG. 5, the gate insulation layer 120 may be formed in a pattern shape partially covering each active layer 110.

Alternatively, the gate insulation layer 120 extends continuously over a

plurality of pixels or light-emitting regions, and may be commonly included in the first to third transistors TR1, TR2 and TR3.

The gate electrode 130 may overlap the channel region of the active layer 110 in the third direction.

The gate insulation layer 120 may be formed through the above-described deposition process to include an inorganic insulating material such as silicon oxide, silicon nitride, silicon oxynitride, etc. According to some embodiments, the gate insulation layer 120 having a patterned shape may be formed as illustrated in FIG. 5 through a photo-lithography process in which the gate electrode 130 is used as an etching mask.

According to some embodiments, the source region and the drain region may be formed in the active layer 110 using the gate electrode 130 and the gate insulation layer 120 as an ion-implantation mask.

An insulating interlayer 140 covering the gate insulation layer 120 and the gate electrode 130 may be formed on the active layer 110. The connection electrodes 150 and 160 that may be in contact with or electrically connected to the active layer 110 may be formed on the insulating interlayer 140.

The insulating interlayer 140 may be formed through the above-described deposition process to include an inorganic insulating material such as silicon oxide, silicon nitride, silicon oxynitride, etc. The insulating interlayer 140 may be formed in a single-layered structure or a multi-layered structure including different materials.

According to some embodiments, when the active layer 110 includes the oxide semiconductor, hydrogen (H) contained in the insulating interlayer 140 may be diffused or transferred to the active layer 110 through a heat-treatment process when forming the insulating interlayer 140. Accordingly, a carrier concentration may be increased by hydrogen, and thus the source region and the drain region having increased conductivity may be formed at lateral portions of the active layer 110.

The connection electrodes 150 and 160 may penetrate the insulating interlayer 140 to be connected to the active layer 110. When the gate insulation layer 120 is continuously and commonly formed in a plurality of the light-emitting regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact holes exposing the source region and the drain region may be formed. A metal layer sufficiently filling the contact holes may be formed on the insulating interlayer 140, and the metal layer may be partially etched to form the source electrode 150 and the drain electrode 160.

The gate electrode 130 and the connection electrodes 150 and 160 may include a metals such as Ag, Mg, Al, W, Cu, Ni, Cr, Mo, Ti, Pt, Ta, Nd, Sc, an alloy thereof or a nitride thereof. The gate electrode 130 and the connection electrodes 150 and 160 may be formed by the above-mentioned deposition process.

A planarization layer 170 covering the connection electrodes 150 and 160 may be formed on the insulating interlayer 140. The planarization layer 170 may accommodate a via structure electrically connecting a pixel electrode 180 and the drain electrode 160.

According to some embodiments, the planarization layer 170 may include an organic material such as polyimide, an epoxy resin, an acrylic resin, polyester, a siloxane resin, a benzocyclobutene (BCB), etc. The planarization layer 170 may be formed by the above-described deposition process or a spin coating process.

The pixel electrode 180 may be formed in each pixel to be electrically connected to the transistors TR1, TR2 and TR3. The pixel electrode 180 may be formed on the planarization layer 170 to be electrically connected to the drain electrode 160.

For example, the planarization layer 170 may be partially etched to form a via hole exposing a top surface of the drain electrode 160. A conductive layer including a metal material or a transparent forming conductive oxide may be formed on a top surface of the planarization layer 170 to sufficiently fill the via hole, and the conductive layer may be etched to form the pixel electrode 180.

The pixel electrode 180 may serve as an anode and may include a conductive material with a high work function to promote a hole injection. The pixel electrode 180 may serve as a transmissive electrode. The pixel electrode 180 may include a transparent conductive oxide such as indium tin oxide (ITO), indium zinc oxide (IZO), zinc oxide (ZnO), indium tin oxide (ITZO), etc.

The pixel electrode 180 may serve as a transflective electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn, and Zn, or an alloy of two or more therefrom.

The pixel electrode 180 may have a single-layered structure or a multi-layered structure. For example, the pixel electrode 180 may have a triple-layered structure of ITO/Ag/ITO.

A pixel defining layer PDL exposing a top surface of the pixel electrode 180 may be formed on the planarization layer 170. A light-emitting region ELR (see FIG. 4) may be defined by a sidewall of the pixel defining layer PDL. A green light-emitting region, a blue light-emitting region and a red light-emitting region may be separated and defined by the pixel defining layer PDL, and the light-emitting devices ED1, ED2 and ED3 may correspond to a green light-emitting device, a blue light-emitting device and the red light-emitting device, respectively.

According to some embodiments, all of the light-emitting device ED1, ED2 and ED3 may be white light-emitting devices or blue light-emitting devices.

As illustrated in FIG. 5, when a sidewall of the pixel defining layer PDL has an inclined shape, the light-emitting region ELR may be defined by an edge where a top surface and the sidewall of the pixel defining layer PDL meet each other.

The pixel defining layer PDL may be formed through exposure and development processes after coating a photo-sensitive organic material such as a polysiloxane resin, a polyimide resin or an acrylic resin. According to some embodiments, the pixel defining layer PDL may be formed by a printing process such as an inkjet printing process using a polymer material or an inorganic material.

The light-emitting portion EL may be located in each light-emitting region ELR formed by the pixel defining layer PDL. According to some embodiments, the light-emitting portion EL may include an emission layer including an organic light-emitting material. For example, the light-emitting portion EL may be formed by a processes such as a vacuum deposition, a spin coating, an inkjet printing, a laser printing, a casting, a laser thermal transfer, etc.

A counter electrode 190 may be located on top surfaces of the pixel defining layer PDL and the light-emitting portion EL. The counter electrode 190 may be a common electrode that may be continuously provided for a plurality of the light-emitting regions or the pixels.

The counter electrode 190 may serve as an electron injection electrode or a cathode. The counter electrode 190 may include a metal, an alloy, an electrically conductive compound, etc., having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. These may be used alone or in a combination of two or more therefrom.

The counter electrode 190 may be provided as a transmissive electrode, a transflective electrode or a reflective electrode. The counter electrode 190 may have a single-layered structure or a multi-layered structure.

The light-emitting devices ED1, ED2 and ED3 may be defined by the above-described pixel electrode 180, the light-emitting portion EL and the counter electrode 190. The light-emitting devices ED1, ED2 and ED3 may serve as organic light-emitting diode (OLED) devices. Elements and structures of the light-emitting portion EL and the light-emitting devices ED1, ED2 and ED3 will be described in more detail with reference to FIGS. 6A and 6B.

An encapsulation layer TFE may be formed on the counter electrode 190. The encapsulation layer TFE may be located on the pixel defining layer PDL and the light-emitting devices ED1, ED2 and ED3 to protect the light-emitting devices ED1, ED2 and ED3 from moisture or oxygen.

The encapsulation layer TFE may include an inorganic layer including silicon nitride (SiNx), silicon oxide (SiOx), indium tin oxide, indium zinc oxide or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof; or a combination of the inorganic layer and the organic layer.

The encapsulation layer TFE may be formed in a single-layered structure or a multi-layered structure. According to some embodiments, the encapsulation layer TFE may have a sequential stacked structure of a first encapsulation layer, an organic layer and a second inorganic layer.

A bank BK and a color conversion layer CCL may be located on the encapsulation layer TFE. The color conversion region CCR (see FIG. 4) may be defined by a sidewall of the bank BK. The color conversion layer CCL may be formed in the color conversion region CCR. For example, the bank BK may include a polymer resin material and may be formed by a photo-lithography process including exposure and development processes.

The color conversion layer CCL may include a first color conversion layer CCLG, a second color conversion layer CCLB and a third color conversion layer CCLR corresponding to the first light-emitting device ED1, the second light-emitting device ED2 and the third light-emitting device ED3, respectively, to overlap in the third direction.

The color conversion layer CCL may include quantum dots. The quantum dots may include a group II-VI compound, a group III-VI compound, a group III-V compound, a group III-V compound, a group IV-VI compound, a group IV element, a group IV compound, or a combination thereof.

The quantum dot may include a core including the above-described compound and may include a shell surrounding the core. The shell may include an inorganic oxide or a semiconductor compound. The semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, AlSb, AlSb, etc.

For example, a color of the emitted light may be adjusted according to a particle size of the quantum dot. The quantum dots may be classified into a blue quantum dot, a red quantum dot and a green quantum dot.

According to some embodiments, a blue light having a central wavelength in, e.g., a range from 420 nm to 480 nm may be generated from the light emitting portion EL. The first color conversion layer CCLG corresponding to the first light-emitting device ED1 and the first pixel PX-G may convert the blue light into a green light having a central wavelength in, e.g., a range from 500 nanometers (nm) to 580 nm.

The second color conversion layer CCLB corresponding to the second light-emitting device ED2 and the second pixel PX-B may transmit the blue light. In this case, the second color conversion layer CCLB may not include the quantum dots and may include a scattering material. The scattering material may include TiO₂, ZnO, Al₂O₃, SiO₂, hollow silica, etc. These may be used alone or in a combination of two or more therefrom.

The third color conversion layer CCLR corresponding to the third light-emitting device ED3 and the third pixel PX-R may convert the blue light into a red light having a central wavelength in, e.g., a range from 600 nm to 670 nm.

The color conversion layers CCLG, CCLB and CCLR may further include a binder resin for dispersing the quantum dots and/or the scattering material. The binder resin may include an acryl-based resin, a urethane-based resin, a silicone-based resin, an epoxy-based resin, etc.

According to some embodiments of the present disclosure, a reflective layer RFL may be formed on a sidewall of the bank BK and a top surface of the color conversion layer CCL. According to some embodiments, a capping layer 220 may be formed between the reflective layer RFL and the color conversion layer CCL.

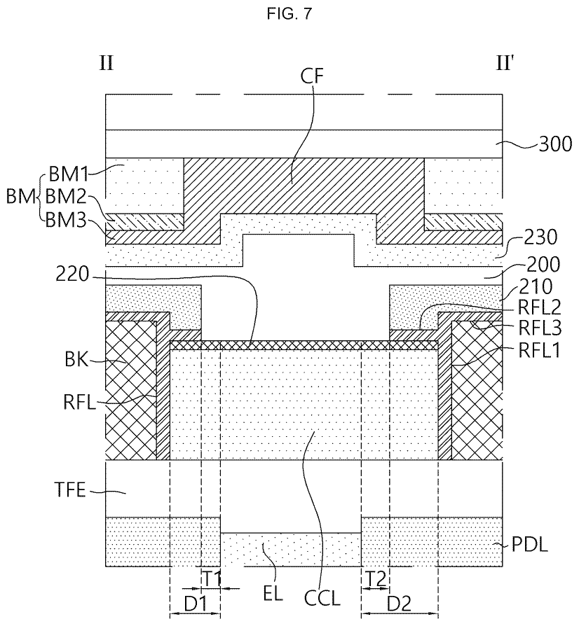

The reflective layer RFL may also be formed on a top surface of the bank BK. The structure and arrangement of the reflective layer RFL will be described in more detail with reference to FIG. 7.

The reflective layer RFL may reflect a light emitted from the color conversion layer CCL, and may increase a light-emission efficiency and a color conversion efficiency by a light-recycling. Further, a luminance of the display device DD may be increased.

According to some embodiments, the reflective layer RFL may include a metal or an inorganic material including the metal. For example, the reflective layer RFL may include aluminum (AI) and/or an inorganic material such as an oxide or a nitride including aluminum.

The capping layer 220 may be provided as a protective layer of the color conversion layer CCL, and may serve as a low refractive index layer (e.g., a first low refractive index layer). For example, the capping layer 220 may be formed using an inorganic insulating material such as silicon oxide, silicon nitride, aluminum oxide, etc., and/or an organic insulating material such that a refractive index difference from the color conversion layer CCL may be 0.1 or more.

As the color conversion layer CCL may be protected by the capping layer 220, the light-emission efficiency and the light-recycling may be further promoted through a reflection at an interface with the color conversion layer CCL. The capping layer 220 may entirely cover a top surface of the color conversion layer CCL.

A shielding layer 210 may be located on the reflective layer RFL. The shielding layer 210 may be formed as a colored layer including a colorant material such as a dye or a pigment. For example, the shielding layer 210 may include a blue color material or a black color material. The shielding layer 210 may suppress a reflection of an external light generated from an outer surface of the reflective layer RFL.

The color filter CF may be located on a bottom surface of the upper substrate 300 (a surface facing the lower substrate 100). The color filter CF may be arranged to overlap the color conversion layer CCL of a corresponding pixel in the third direction. A color control structure corresponding to each pixel or each emission region may be defined by the color filter CF and the color conversion layer CCL.

The color filter CF may include a first color filter CFG, a second color filter CFB and a third color filter CFR that correspond to or overlap the first color conversion layer CCLG, the second color conversion layer CCLB and the third color conversion layer CCLR, respectively.

The color filter CF may selectively transmit ay light of a specific wavelength band, and may absorb a remaining (or substantially all of a remaining) light. Accordingly, a color purity of the display device DD may be increased, and reflection of the external light may be decreased.

The first color filter CFG may transmit a green light having the central wavelength in, e.g., a range from 500 nm to 580 nm. The second color filter CFB may transmit a blue light having a central wavelength in, e.g., a range from 420 nm to 480 nm. The third color filter CFR may transmit a red light having a central wavelength in, e.g., a range from 600 nm to 670 nm.

Each color filter CF may include a photo-sensitive polymer resin and a colorant material including a pigment and/or a dye. The first color filter CFG may include a green pigment and/or a green dye, the second color filter CFB may include a blue pigment and/or a blue dye, and the third color filter CFR may include a red pigment and/or a red dye.

The color filter CF may be defined or partitioned by a light-shielding portion BM. A plurality of the light-shielding portions BM may be spaced apart from each other while exposing a portion of a bottom surface of the upper substrate 300. A plurality of the color filters CF may be arranged between the light-shielding portions BM.

The light-shielding portion BM may have a multi-layered structure. The light-shielding portion BM may include a first light-shielding portion BM1 and a second light-shielding portion BM2 sequentially stacked from the bottom surface of the upper substrate 300.

According to some embodiments, the first light-shielding portion BM1 may include a blue colorant, and the second light blocking portion BM2 may include a red colorant material or a black colorant. In this case, in the second pixel PX-B, a portion of the first light-shielding portion BM1 exposed between the second light-shielding portions BM2 may serve as the second color filter CFB (e.g., a blue color filter).

A portion of the first color filter CFG and/or the third color filter CFR may extend in the first direction to contact a bottom surface of the second light-shielding portion BM2. In this case, the portion of the first color filter CFG and/or the third color filter CFR may serve as the third light-shielding portion BM3.

A low refractive index layer 230 (e.g., a second low refractive index layer) may be formed on the color filters CF. The light-recycling and the light-emission efficiency may be additionally promoted by an interfacial reflection of the low refractive index layer 230, and the luminance of the display device DD may be increased. For example, the low refractive index layer 230 may be formed using a photocurable transparent resin such as an epoxy resin, an acrylic resin, etc.

The low refractive index layer 230 may be commonly and continuously formed on a plurality of the pixels or the color filters CF.

The upper structure US including the upper substrate 300, the color filter CF, the light-shielding portion BM and the low refractive index layer 230 as described above may be laminated or combined with the lower structure LS using a filler layer 200.

The filler layer 200 may be formed using a photocurable resin material. For example, the filler layer 200 may include an epoxy resin or an acrylate resin.

FIGS. 6A and 6B are schematic cross-sectional views illustrating light-emitting devices according to some embodiments.

Referring to FIGS. 6A and 6B, the light-emitting device ED may include the light-emitting portion EL located between the pixel electrode 180 and the counter electrode 190.

As illustrated in FIG. 6A, the light-emitting portion EL may include a hole transport layer HTL, an emission layer EML and an electron transport layer ETL. According to some embodiments, the hole transport layer HTL, the emission layer EML, the electron transport layer ETL and the counter electrode 190 may be sequentially stacked from a top surface of the pixel electrode 180.

According to some embodiments, a hole injection layer may be further located between the pixel electrode 180 and the hole transport layer HTL. An electron injection layer may be further located between the counter electrode 190 and the electron transport layer ETL.

According to some embodiments, the light-emitting portion EL may include the emission layer EML including an organic light-emitting material capable of emitting a blue light having a central wavelength in, e.g., a range from 420 nm to 480 nm.

As illustrated in FIG. 6B, the light-emitting portion EL may include a plurality of light-emitting structures ES1, ES2 and ES3. Each of the light-emitting structures ES1, ES2 and ES3 may include the hole transport layer, the emission layer and the electron transport layer. According to some embodiments, the light-emitting device ED of FIG. 6B may be a light-emitting device having a tandem structure.

Charge generation layers CGL1 and CGL2 may be located between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

According to some embodiments, the first light-emitting structure ES1, the first charge generation layer CGL1, the second light-emitting structure ES2, the second charge generation layer CGL2, the third light-emitting structure ES3 and the counter electrode 190 may be sequentially stacked from the top surface of the pixel electrode 180.

According to some embodiments, as illustrated in FIG. 5, the light-emitting portion EL may be patterned limitedly within the light-emitting region defined by the pixel defining layer PDL. Accordingly, the light-emitting portions EL may be separated from each other in the form of an island in each of a plurality of the pixels.

According to some embodiments, the light-emitting portion EL may extend continuously and commonly throughout the plurality of the pixels and top surfaces of the pixel defining layer PDL.

FIG. 7 is a cross-sectional view taken along a line II-II′ of FIG. 4 in a thickness direction. For convenience of descriptions, illustration of the counter electrode 190 is omitted from FIG. 7, and illustration of structures under the pixel defining layer PDL and the light-emitting portion EL is omitted. Hereinafter, detailed descriptions on elements, structures and/or materials described with reference to FIG. 1 to FIG. 6 are omitted.

FIG. 7 provides an example cross-sectional view of the first pixel PX-G, and descriptions with reference to FIG. 7 may be commonly applied to the second pixel PX-B and the third pixel PX-R.

Referring to FIGS. 4 and 7, as described above, the color conversion region CCR may be defined by the sidewall of the bank BK. The color conversion region CCR may refer to a first opening OP1 in which the color conversion layer CCL is formed. The entire top surface of the light-emitting portion EL may be covered or exposed by the first opening OP1 in a plan view of FIG. 4.

As described above, the light-emitting region ELR may be defined by the sidewall of the pixel defining layer PDL. The light-emitting region ELR may refer to a second opening OP2 in which the light-emitting portion EL is formed. Each pixel region may be defined as a region including the color conversion region CCR and the light emitting region ELR.

According to some embodiments, the color conversion region CCR may have a larger area than that of the light-emitting region ELR and may entirely cover the light-emitting region ELR. For example, the second opening OP2 may be completely (or substantially completely) included in the first opening OP1 in the plan view of FIG. 4.

The reflective layer RFL may be formed on a surface of the bank BK, and may cover a peripheral portion or an edge portion of a top surface of the color conversion layer CCL. The reflective layer RFL may include a first reflective portion RFL1, a second reflective portion RFL2 and a third reflective portion RFL3.

The first reflective portion RFL1 may be formed on an inner sidewall of the bank BK. The second reflective portion RFL2 may be formed on a peripheral portion of the top surface of the color conversion layer CCL. The third reflective portion RFL3 may be formed on a top surface of the bank BK.

The first reflective portion RFL1, the second reflective portion RFL2 and the third reflective portion RFL3 may be formed as an integral member connected to each other.

According to some embodiments, the first reflective portion RFL1 and the third reflective portion RFL3 may be formed directly on the surface of the bank BK to be in contact with the surface. The capping layer 220 may be formed between the second reflective portion RFL2 and the color conversion layer CCL.

As illustrated in FIG. 4, a third opening OP3 may be defined by an edge of the second reflective portion RFL2 of the reflective layer RFL. The third opening OP3 may have an area larger than that of the light-emitting region ELR or the second opening OP2. The light-emitting region ELR or the second opening OP2 may be completely (or substantially completely) included in the third opening OP3 in the plan view of FIG. 4. A boundary of the third opening OP3 in the plan view of FIG. 4 may be located between a boundary of the first opening OP1 and a boundary of the second opening OP2.

Accordingly, the second reflective portion RFL2 may not cover the light-emitting portion EL in the third direction.

For example, a light emitted from the pixel electrode 180 of the first light-emitting device ED1 in a direction to an outside the first color filter CFG may be reflected back to the pixel electrode 180 by the first reflective portion RFL1 and the second reflective portion RLF2, and then may be incident toward the first color filter CFG. Accordingly, a light efficiency in the first color conversion layer CCL and the first color filter CFG may be relatively improved.

Additionally, the second reflective portion RFL2 may not overlap the light-emitting portion EL so that a light emitted in a vertical direction (the third direction) directly to the color conversion layer CCL and the color filter CF may not be shielded.

According to some embodiments of the disclosure, a peripheral portion of each pixel region may include a first portion C1 and a second portion C2. The first portion C1 and the second portion C2 may be portions having different spacing distances between the light-emitting region ELR and the color conversion region CCR. A left portion of FIG. 7 represents the first portion C1 and a right portion of FIG. 7 represents the second portion C2.

A first spacing distance between the light-emitting region ELR and the color conversion region CCR at the first portion C1 is indicated as D1. A second spacing distance between the light emitting-region ELR and the color conversion region CCR at the second portion C2 is indicated as D2. The second spacing distance D2 of the second portion C2 may be greater than the first spacing distance D1 of the first portion C1.

The spacing distance may be the shortest distance between the boundaries of the light-emitting region ELR and the color conversion region CCR in the plan projection view as illustrated in FIG. 4.

For example, the spacing distance may be the shortest distance in a horizontal direction between a vertical extension line from the sidewall (or an edge where the top surface meets the sidewall) of the pixel defining layer PDL and a vertical extension line from a sidewall (or an edge where the top surface meets the sidewall) of the bank BK.

A separation distance between an edge of the reflective layer RFL and the light-emitting region ELR at the first portion C1 is indicated as a first separation distance T1, and a separation distance between the edge of the reflective layer RFL and the light-emitting region ELR at the second portion C2 is indicated as a second separation distance T2. The separation distance may be the shortest distance between boundaries between the second reflective portion RFL2 and the light-emitting region ELR in the plan projection view as illustrated in FIG. 4.

For example, the separation distance may be the shortest distance in the horizontal direction between the vertical extension line from the sidewall (or the edge where the top surface meets the sidewall) of the pixel defining layer PDL and a vertical extension line from the edge of the second reflective portion RFL2.

According to some embodiments of the present disclosure, the second separation distance T2 may be greater than or equal to the first separation distance T1. According to some embodiments, the second separation distance T2 may be greater than the first separation distance T1.

For example, the first spacing distance D1 may be in a range of 4 μm to 6 μm, and the second spacing distance D2 may be in a range of 10 μm to 20 μm. The first separation distance T1 may be in a range of 2 μm to 3 μm, and the second separation distance T2 may be in a range of 3 μm to 6 μm.

According to the above-described embodiments, the light recycling or light extraction effect may both be relatively improved by adjusting the structure of the second reflective portion RFL2 according to a peripheral shape in the pixel region.

According to some embodiments, in a region in which a width between the light-emitting region ELR and the color conversion region CCR is relatively small, an edge of the reflective layer RFL or the second reflective portion RFL2 may be adjusted to be closer to the light-emitting region ELR to induce a sufficient light recycling. In a region in which a width between the light-emitting region ELR and the color conversion region CCR is relatively large, the edge of the reflective layer RFL or the second reflective portion RFL2 may be retreated from the boundary of the light-emitting region ELR to obtain sufficient aperture ratio and light extraction area.

As illustrated in FIG. 4, the peripheral portion of the pixel region may include a third portion C3 having a maximum spacing distance (a third spacing distance D3) between the light-emitting region ELR and the color conversion region CCR. A separation distance (a third separation distance T3) between the reflective layer RFL and the light-emitting region ELR at the third portion C3 may be greater than or equal to the second separation distance T2. According to some embodiments, the third separation distance T3 may be greater than the second separation distance T2.

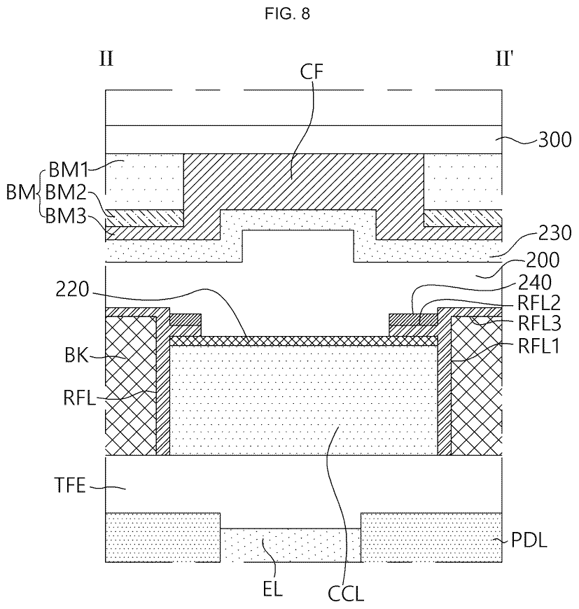

FIGS. 8 to 10 are schematic cross-sectional views illustrating display devices according to some embodiments. FIGS. 8 to 10 are cross-sectional views taken along a line II-II′ of FIG. 4 in a thickness direction. For convenience of descriptions, illustrations of the counter electrode 190 is omitted and illustrations of structures under the pixel defining layer PDL and the light emitting portion EL are omitted in FIGS. 8 to 10. Hereinafter, some detailed descriptions of elements, structures, and/or materials the same (or substantially the same) as those described with reference to FIG. 7 may be omitted.

Referring to FIG. 8, a non-colored shielding layer 240 may be located on the second reflective portion RFL2. The non-colored shielding layer 240 may be a shielding layer that does not contain a colorant material such as a dye or a pigment.

The non-colored shielding layer 240 may entirely cover a top surface of the second reflective portion RFL2 and may be in direct contact with the top surface of the second reflective portion RFL2. According to some embodiments, the non-colored shielding layer 240 may not be formed on the third reflective portion RFL3.

The non-colored shielding layer 240 may be formed of an inorganic layer having a low reflectivity. Accordingly, reflection of an external light generated from an outer surface of the second reflective portion RFL2 may be suppressed. According to some embodiments, the non-colored shielding layer 240 may include an oxide including molybdenum (Mo). According to some embodiments, the non-colored shielding layer 240 may include an oxide (e.g., MoTaOx) containing molybdenum (Mo) and tantalum (Ta).

A thickness of the non-colored shielding layer 240 may be in a range from 500 Å to 2,000 Å, or from 800 Å to from 1500 Å.

As described above, the non-colored shielding layer 240 may be formed on the second reflective portion RFL2 instead of the shielding layer 210 formed of the colored material layer. Accordingly, non-curing of the filler layer 200, a discoloration of the shielding layer 210, etc., may be prevented or reduced due to a side reaction between a component included in the colored material layer and a functional group (e.g., an epoxy group) included in the filler layer 200.

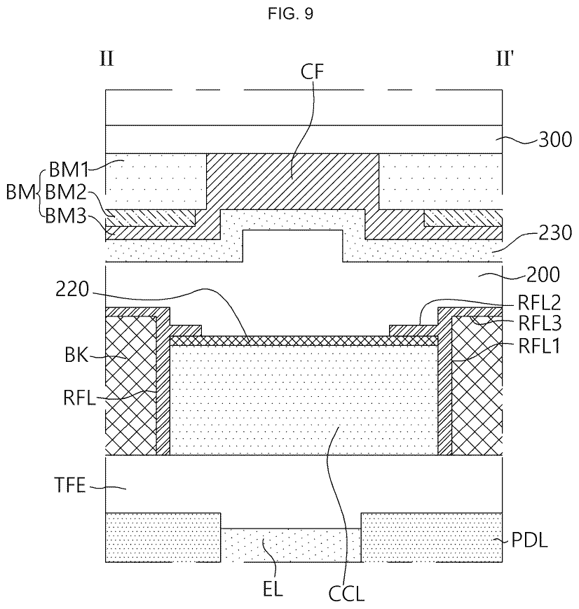

Referring to FIG. 9, the shielding layer 210 may be omitted, and a width of the first light-shielding portion BM1 included in the light-shielding portion BM may be increased.

According to some embodiments, the first light-shielding portion BM1 may protrude from a sidewall of the second light-shielding portion BM2. The first light-shielding portion BM1 may overlap the second reflective portion RFL2 in a thickness direction or a vertical direction, and may completely cover (or substantially completely cover) the second reflective portion RFL2 in a plan view (when projected in the same plane as illustrated in FIG. 4).

Accordingly, reflection of an external light caused by the second reflective portion RFL2 may be sufficiently reduced while removing or reducing the side reaction between the colored material included in the shielding layer 210 and the filler layer 200.

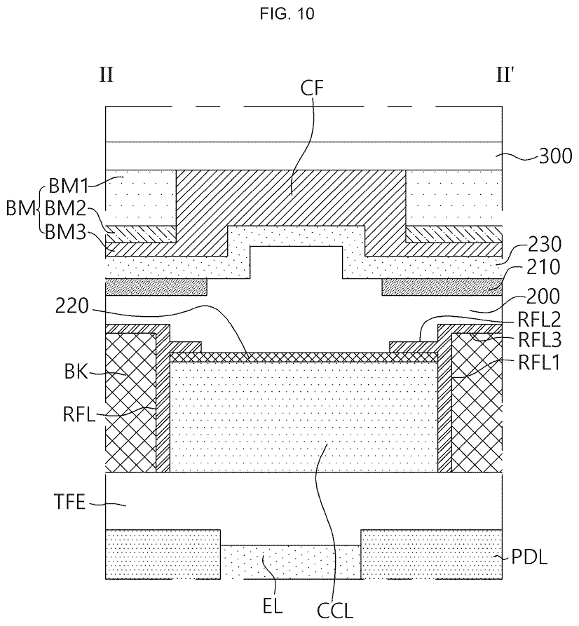

Referring to FIG. 10, the shielding layer 210 may be spaced apart from the reflective layer RFL in the thickness direction. For example, the shielding layer 210 may be in contact with the low refractive index layer 230 formed on the color filter CF, and may be physically separated from the second reflective portion RFL2 and the third reflective portion RFL3.

The shielding layer 210 may overlap the second reflective portion RFL2 in the thickness direction or the vertical direction, and may completely cover (or substantially completely cover) the second reflective portion RFL2 in the plan view. According to some embodiments, the shielding layer 210 may overlap the second reflective portion RFL2 and the third reflective portion RFL3 in the thickness direction or the vertical direction, and may completely cover (or substantially completely cover) the second reflective portion RFL2 and the third reflective portion RFL3 in the plan view.

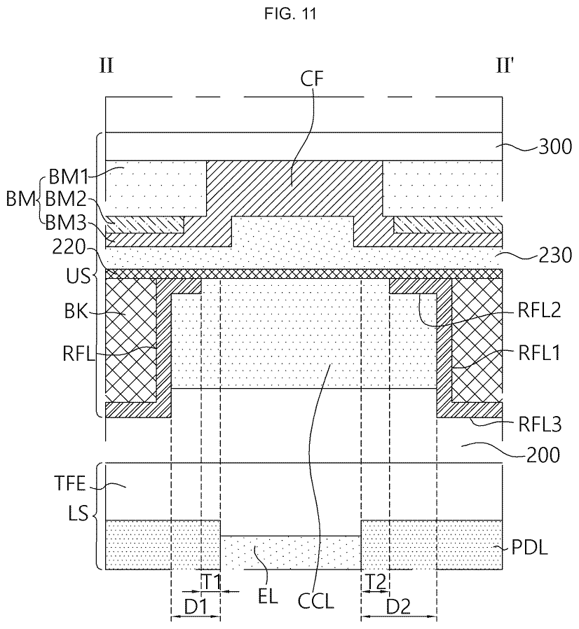

FIG. 11 is a schematic cross-sectional view illustrating a display device according to some embodiments. FIG. 11 is a cross-sectional view taken along a line II-II′ of FIG. 4 in a thickness direction. For convenience of descriptions, illustration of the counter electrode 190 is omitted from FIG. 11, and illustration of structures under the pixel defining layer PDL and the light emitting portion EL is omitted. Hereinafter, detailed descriptions on elements, structures and/or materials described with reference to FIG. 4 to FIG. 7 are omitted.

Referring to FIG. 11, the color conversion layer CCL and the bank BK may be included in the upper structure US. Accordingly, the upper structure US may be provided as a structure including the color control structure that includes the color filter CF and the color conversion layer CCL. Further, the light-shielding portion BM and the reflective layer RFL may be included in the upper structure US.

As described with reference to FIGS. 3 and 5, the lower structure LS may include the pixel circuit formed on the lower substrate 100, the light-emitting device ED including the light-emitting portion EL and the pixel defining layer PDL.

The filler layer 200 may be located between the color conversion layer CCL and the light-emitting portion EL to combine the upper structure US and the lower structure LS. According to some embodiments, the filler layer 200 may be located between the color conversion layer CCL and the encapsulation layer TFE.

As described above, the reflective layer RFL may include the first reflective portion RFL1, the second reflective portion RFL2 and the third reflective portion RFL3. The first reflective portion RFL1 may be formed on a sidewall of the bank BK. The third reflective portion RFL3 may be formed on a bottom surface of the bank BK.

The second reflective portion RFL2 may cover a peripheral portion or an edge portion of an upper portion of the color conversion region CCR or color conversion layer CCL. According to some embodiments, top surfaces of the second reflective portion RLF2 and the color conversion layer CCL may be located at the same (or substantially the same) plane.

The capping layer 220 may cover the top surfaces of both the color conversion layer CCL and the second reflective portion RFL2. The capping layer 220 may be in contact with the top surfaces of the color conversion layer CCL and the second reflective portion RFL2. According to some embodiments, the capping layer 220 may also cover a top surface of the bank BK.

The low refractive index layer 230 may be located on the capping layer 220. Accordingly, the low refractive index layer 230 may be located between the color filter CF and the capping layer 220.

The relationship between the first spacing distance D1, the second spacing distance D2, the first separation distance T1, and the second separation distance T2 described with reference to FIG. 7 may also be applied to the display device DD or the pixel structure according to some embodiments as illustrated in FIG. 11.

As described above, the second spacing distance D2 may be greater than the first spacing distance D1, and the second separation distance T2 may be greater than or equal to the first separation distance T1. According to some embodiments, the second separation distance T2 may be greater than the first separation distance T1.

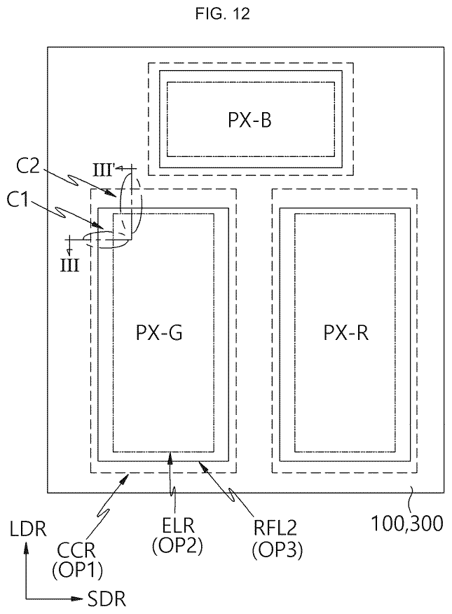

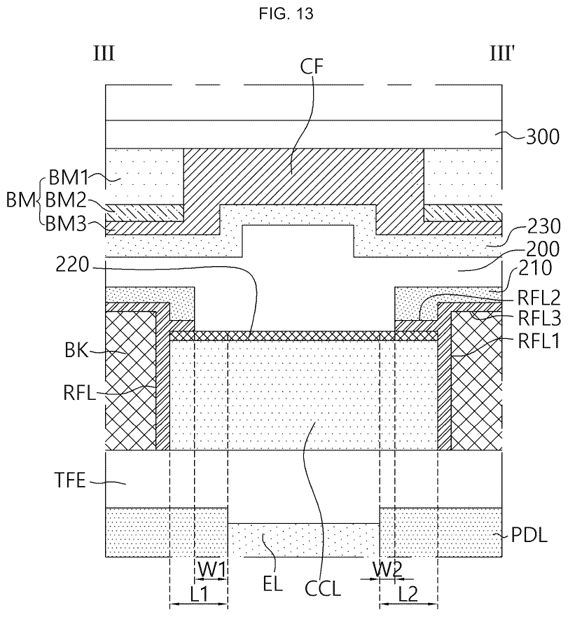

FIG. 12 is a plan view illustrating a pixel arrangement of a display device according to some embodiments. FIG. 13 is a cross-sectional view taken along line III-III′ of FIG. 12 in a thickness direction.

Referring to FIGS. 12 and 13, each of the pixels PX-G, PX-B, and PX-R may have a shape in which a separation distance between the light-emitting region ELR (or the second opening OP2) and the color conversion region CCR (or the first opening OP1) is maintained constant or uniform (or substantially constant or uniform). Thus, a first spacing distance L1 and a second spacing distance L2 at different peripheral portions may be the same (or substantially the same).

Each of the pixels PX-G, PX-B, and PX-R or the pixel region may have a major axis direction side and a minor axis direction side. According to some embodiments, at least one of the pixels PX-G, PX-B, or PX-R may have a rectangular shape having a major axis length and a minor axis length.

As illustrated in FIGS. 12 and 13, separation distances at a first portion C1 and a second portion C2 may be different from each other. A first separation distance W1 between an edge of the second reflective portion RFL2 and the light-emitting region ELR at the first portion C1 may be greater than a second separation distance W2 between the edge of the second reflective portion RFL2 and the light-emitting region ELR at the second portion C2.

According to some embodiments, the first portion C1 may be a portion of the major axis direction side of a peripheral portion of the pixel region. The first separation distance W1 at the first portion C1 may be a distance in a minor axis direction SDR. The second portion C2 may be a portion of the minor axis direction side of the peripheral portion of the pixel region. The second separation distance W2 in the second portion C2 may be a distance in a major axis direction LDR.

Accordingly, the separation distance between the edge of the second reflective portion RF2 and the light-emitting region ELR in the minor axis direction may be relatively increased, so that an aperture ratio and a light extraction area of the pixel region may be increased. The separation distance between the edge of the second reflective portion RF2 and the light-emitting region ELR in the major axis direction may be relatively decreased, so that a light emission efficiency through a light recycling of the pixel region may be relatively improved.

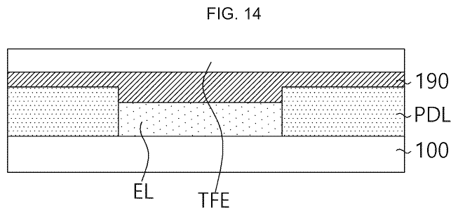

FIGS. 14 to 19 are schematic cross-sectional views illustrating a method of manufacturing a display device according to some embodiments. For example, FIGS. 14 to 19 are cross-sectional views illustrating a method of manufacturing a display device described with reference to FIGS. 4 to 7.

For convenience of descriptions, illustrations of the pixel circuit, the insulation layers, the pixel electrode, etc., between the lower substrate 100 and the light-emitting portion EL are omitted in FIG. 14 to FIG. 19. Repeated descriptions of the materials described with reference to FIG. 4 to FIG. 7 are omitted.

Referring to FIG. 14, as described with reference to FIG. 5, the pixel circuit including the transistor may be formed on the lower substrate 100, and the pixel electrode connected to the pixel circuit may be formed. The pixel defining layer PDL that may at least partially expose a top surface of the pixel electrode may be formed, and the light-emitting portion EL may be formed in the light-emitting region defined by the pixel defining layer PDL.

The counter electrode 190 may be formed on the pixel defining layer PDL and the light-emitting portion EL, and the encapsulation layer TFE may be formed on the counter electrode 190.

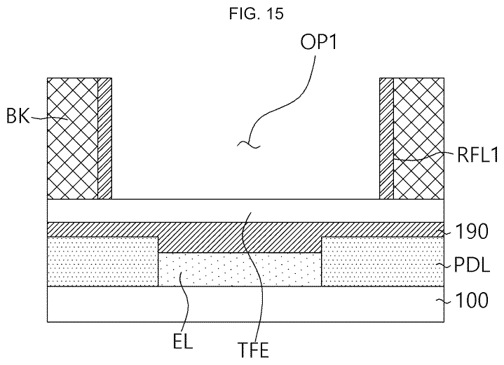

Referring to FIG. 15, the bank BK may be formed on the encapsulation layer TFE, and the first reflection portion RFL1 may be formed on a sidewall of the bank BK.

According to some embodiments, a photosensitive organic layer such as a photoresist layer may be formed, and the photosensitive organic layer may be partially removed by exposure and development processes to form the bank BK. The color conversion region CCR or the first opening OP1 (see FIG. 4) may be defined by the bank BK.

Thereafter, a first reflective layer may be formed on a top surface and an inner wall of the bank BK, and a bottom surface of the first opening OP1 by a deposition process such as a CVD process, a sputtering process, etc. The first reflective portion RFL1 may be formed by removing a portion of the first reflective layer formed on a bottom surface of the first opening OP1 by a photo-lithography process.

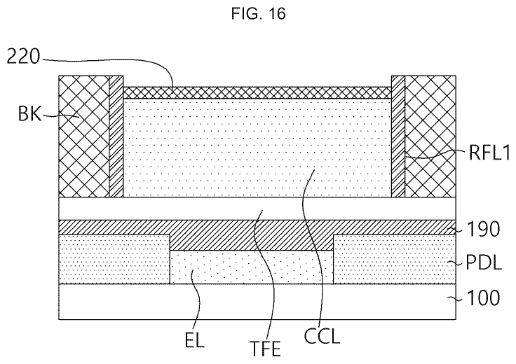

Referring to FIG. 16, the color conversion layer CCL and the capping layer 220 may be formed in the first opening OP1.

The color conversion layer CCL may be formed in the first opening OP1 by a printing process such as an inkjet printing process. For example, the capping material may be deposited on the bank BK and the color conversion layer CCL, and then the capping layer 220 may be formed by partially removing a layer portion deposited on the top surface of the bank BK by the photo-lithography process.

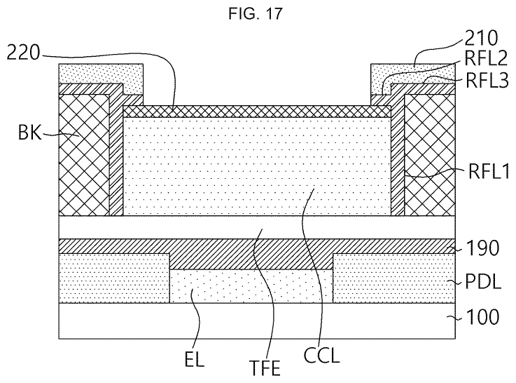

Referring to FIG. 17, the third reflective portion RFL3 and the second reflective portion RFL2 may be formed on the top surfaces of the bank BK and the capping layer 220, respectively.

A second reflective layer including the same material as that of the first reflective layer may be formed on the top surface of the bank BK and the top of the capping layer 220 by a deposition process such as a CVD process or a sputtering process. The second reflective portion RFL2 and the third reflective portion RFL3 may be formed by removing a portion of the second reflective layer that covers the light-emitting portion EL.

When projected from a plan view, the second reflective portion RFL2 may not cover the light-emitting portion EL and may be formed to satisfy the above-described relationship of the separation distance. The third reflective portion RFL3 may be formed on the top surface of the bank BK.

Thereafter, the shielding layer 210 covering the second reflective portion RFL2 and the third reflective portion RFL3 may be formed. For example, the composition including a colorant material and a photosensitive binder resin may be coated, and then the coated layer may be partially removed by exposure and development processes to form the shielding layer 210.

The lower structure LS may be formed through the process described with reference to FIGS. 14 to 17.

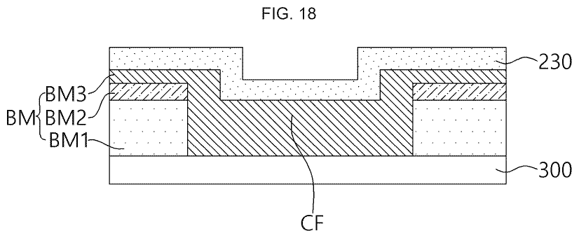

Referring to FIG. 18, the upper structure US including the color filter CF may be formed.

The light-shielding portion BM may be formed on the upper substrate 300 to define an area in which the color filter CF is formed. The light-shielding portion BM may be formed to include a stacked structure of the first light-shielding portion BM1 and the second light-shielding portion BM2. The first light-shielding portion BM1 and the second light-shielding portion BM2 may be sequentially formed by using a resin composition including colorant materials of different colors.

A resin composition including a colored material having a color of a corresponding pixel may be formed within the region defined by the light-shielding portion BM to form the color filter CF. A portion of the color filter CF extending on a surface of the second light-shielding portion BM2 may be included in the light-shielding portion as the third light-shielding portion BM3.

The low refractive index layer 230 may be formed on the color filter CF. The low refractive index layer 230 may be conformally formed on an entire surface of the color filter CF by a deposition process such as a CVD process or a sputtering process.

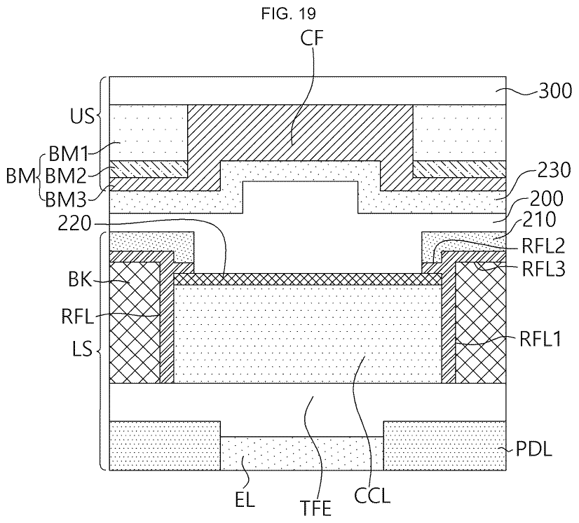

Referring to FIG. 19, the upper structure US and the lower structure LS may be laminated using the filler layer 200. According to some embodiments,, the upper structure US and the lower structure LS may be laminated such that the color filter CF of the upper structure US may face the color conversion layer CCL of the lower structure LS.

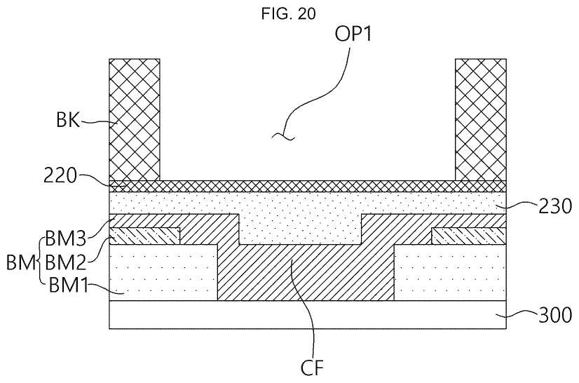

FIGS. 20 to 23 are schematic cross-sectional views illustrating a method of manufacturing a display device according to some embodiments. For example, FIGS. 20 to 23 are cross-sectional views illustrating a method of manufacturing a display device described with reference to FIG. 11.

For convenience of descriptions, illustrations of the pixel circuit, the insulation layers, the pixel electrode, etc., between the lower substrate 100 and the light-emitting portion EL in FIG. 20 to FIG. 23 are omitted. Repeated descriptions of the material described with reference to FIG. 4 to FIG. 7 and FIG. 11 are omitted. Detailed descriptions on processes the same (or substantially the same) as or similar to those described with reference to FIG. 14 to FIG. 19 are omitted.

Referring to FIG. 20, as described with reference to FIG. 18, the light-shielding portion BM, the color filter CF and the low refractive index layer 230 may be formed on the upper substrate 300. Thereafter, the capping layer 220 may be formed on the low refractive index layer 230, and the bank BK may be formed on the capping layer 220.

The capping layer 220 may be formed on an entire top surface of the low refractive index layer 230. The first opening OP1 through which the top surface of the capping layer 220 is partially exposed may be formed by the bank BK. The color conversion region CCR may be defined by the first opening OP1.

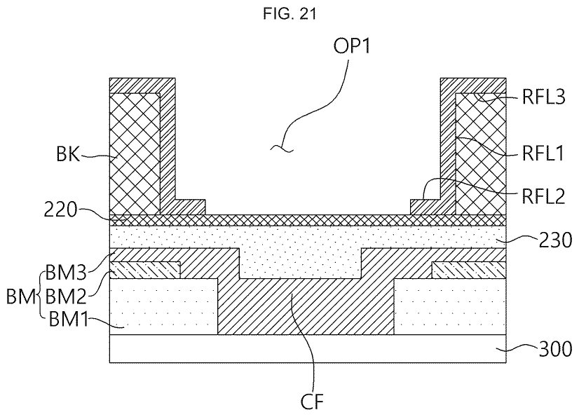

Referring to FIG. 21, a reflective layer may be formed on a sidewall and a top surface of the bank BK and the top surface of the capping layer 220 exposed by the first opening OP1. The reflective portions RFL1, RFL2 and RFL3 may be formed by partially etching a portion of the reflective layer formed on the top surface of the capping layer 220. A portion of the reflective layer formed on the top surface of the bank BK may also be partially etched by the etching process.

A portion of the reflective layer formed on the sidewall of the bank BK may remain as the first reflective portion RFL1, and a portion formed on the top surface of the bank BK may remain as the third reflective portion RFL3 on the bank BK. An edge portion of the reflective layer of the first opening OP1 or on the top surface of the capping layer 220 may remain as the second reflective portion RFL2.

According to some embodiments, a distance between the edge portion and the sidewall of the bank may be variable (not constant). The distance between the edge portion and the sidewall of the bank may be adjusted to satisfy the relationship of the above-described separation distance according to a peripheral portion of the pixel region.

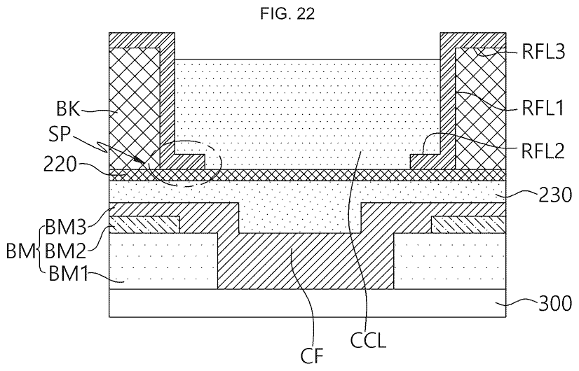

Referring to FIG. 22, the color conversion layer CCL may be formed to fill the first opening OP1. The color conversion layer CCL may be in contact with the first and second reflective portions RFL1 and RFL2 and may partially fill the first opening OP1.

The color conversion layer CCL may include a stepped portion SP formed by the second reflective portion RFL2 at a bottom portion of the first opening OP1.

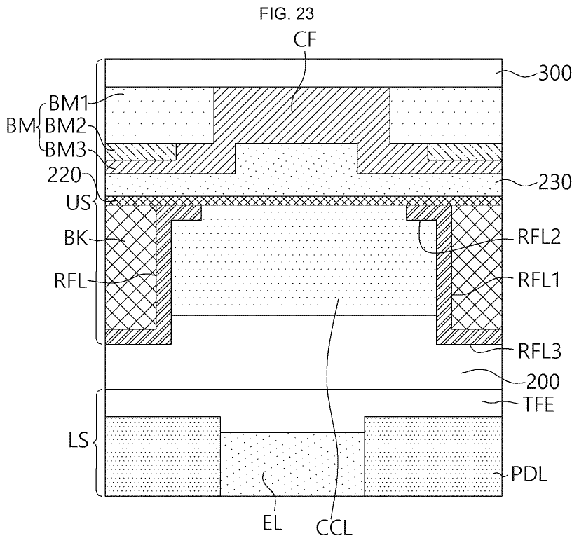

Referring to FIG. 23, the lower structure LS manufactured as described with reference to FIG. 14 may be laminated with the upper structure US manufactured as described with reference to FIGS. 20 to 22 using the filler layer 200.

The upper structure US and the lower structure LS may be combined so that the color conversion layer CCL included in the upper structure US may face the light-emitting device ED including the light-emitting portion EL with the filler layer 200 interposed therebetween.

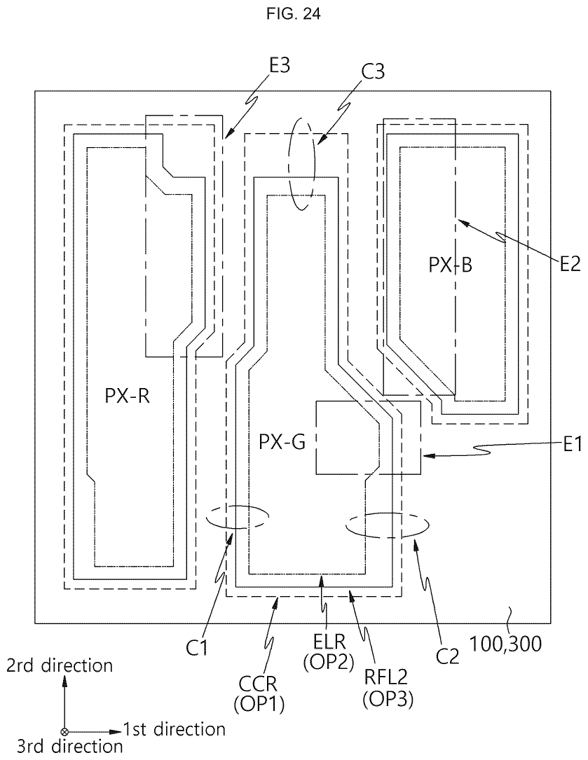

FIG. 24 illustrates a pixel arrangement of a display device according to some embodiments

Although FIG. 4 provides a pixel arrangement according to some embodiments of the present invention, the pixel arrangement of the present disclosed is not limited to the structure illustrated in FIG. 4. The pixel arrangement may be appropriately changed in consideration of increase in a light emission extraction area, an aperture ratio, a light-emission efficiency, etc. For example, the pixel arrangement may be modified as illustrated in FIG. 24.

Referring to FIG. 24, the first pixel PX-G may be located between the second pixel PX-B and the third pixel PX-R. The second pixel PX-B may have an area smaller than an area of each of the first pixel PX-G and the third pixel PX-R.

Each of the third pixel PX-R and the second pixel PX-B may include an expanded portion protruding in the first direction at one end portion in the second direction. An expanded portion (a third expanded portion E3) of the third pixel PX-R and an expanded portion (a second expanded portion E2) of the second pixel PX-B may protrude in directions facing each other.

One end portion of the first pixel PX-G in the second direction may be located between the third expanded portion E3 of the third pixel PX-R and the second expanded portion E2 of the second pixel PX-B. The first pixel PX-G may include the other end portion having an increased width compared to the one end portion, and a first expanded portion E1 protruding from the other end portion in the first direction.

The relationship between the spacing distance (the spacing distance between the light-emitting region ELR and the color conversion region CCR) and the separation distance (the separation distance between the second reflective portion RFL2 and the light-emitting region ELR) at the first portion C1, the second portion C2 and the third portion C3 described with reference to FIG. 4 may be equally applied to the pixel arrangement of FIG. 24.

Hereinafter, an experimental example is provided to enhance understanding of the present disclosure, but the example are provided as a non-limiting example, and is not to be interpreted as limiting the scope of the attached claims. It is clear to those skilled in the art that various changes and modifications to disclosed examples can be made within the scope of the present disclosure and the technical idea.

### Experimental Example

Pixels having the arrangement and shape illustrated in FIG. 24 were manufactured. Specifically, Sample 1 was manufactured to have a structure in which a reflective layer (the second reflective portion RLF2) was omitted from the structure illustrated in FIG. 7.

Sample 2 was manufactured such that a reflective layer (the second reflective portion RLF2) was added to Sample 1, a shielding layer including a colorant material was formed covering the second reflective portion RLF2, and a separation distance between the second reflective portion RFL2 and the light-emitting region ELR was constant.

Sample 3 was manufactured such that the separation distance between the second reflective portion RFL2 and the light-emitting region ELR in Sample 2 was 3 μm at the first portion C1, and 5 μm in the second portion C2.

Sample 4 was manufactured such that a non-colored shielding layer including a MoTaOx material was included instead of the shielding layer including the colorant material in Sample 3.

Sample 5 was manufactured such that the shielding layer including the colorant was omitted from Sample 3 and the first light-shielding portion BM1 protruded to cover the second reflective portion RFL2 as illustrated in FIG. 11.

W efficiencies, T95s (PX-G) and SCI/SCEs of Samples 1 to 5 were measured, and the measurement results are shown in Table 1 below.

The W efficiency and the T95 (PX-G) were measured by setting values from the same reference sample including pixels having a rectangular shape and devoid of a reflective layer as 100%.

TABLE 1

| | W efficiency | | |
|---|---|---|---|
| | (%) | T95 | SCI/SCE(%) |
| Sample 1 | 105.2 | 160.2 | 1.39/0.75 |
| Sample 2 | 105.6 | 159 | 1.32/0.68 |
| Sample 3 | 106.7 | 163.1 | 1.34/0.70 |
| Sample 4 | 105.9 | 158.9 | 1.34/0.68 |
| Sample 5 | 106.4 | 161.0 | 1.31/0.67 |

In sample 2, the W efficiency was increased and the SCE value was decreased as the second reflective portion (RFL2) was added. In sample 3, the W efficiency and T95 were both increased as the separation distance of the second reflective portion was variably adjusted. In Samples 4 and 5, the SCEs were decreased as different structures (the non-colored shielding layer, the protruding first light-shielding portion) were introduced to replace the shielding layer including the colorant material.

What is claimed is:

1. A display device, comprising:
a pixel defining layer defining a light-emitting region;
a light-emitting portion formed within the light-emitting region;
a bank on the pixel defining layer to define a color conversion region that covers the light-emitting region in a plan view and forms a pixel region together with the light-emitting region;
a color conversion layer in the color conversion region; and
a reflective layer on a peripheral portion of a top surface of the color conversion layer,
wherein a peripheral portion of the pixel region comprises a first portion having a first spacing distance between boundaries of the color conversion region and the light-emitting region in the plan view; and a second portion having a second spacing distance between boundaries of the color conversion region and the light-emitting region, and the second spacing distance is greater than the first spacing distance,
wherein a second separation distance in the plan view between boundaries of the reflective layer and the light-emitting region at the second portion is greater than or equal to a first separation distance in the plan view between boundaries of the reflective layer and the light-emitting region at the first portion.

2. The display device of claim 1, wherein the reflective layer comprises a first reflective portion formed on a sidewall of the bank and a second reflective portion arranged on the peripheral portion of the top surface of the color conversion layer, and
the first separation distance and the second separation distance are distances between an edge of the second reflective portion and a boundary of the light-emitting region.

3. The display device of claim 2, further comprising a shielding layer on the second reflective portion to completely cover a top surface of the second reflective portion in a thickness direction, the shielding layer comprising a colorant material.

4. The display device of claim 3, wherein the reflective layer further comprises a third reflective portion on a top surface of the bank, and
the shielding layer commonly covers top surfaces of the second reflective portion and the third reflective portion.

5. The display device of claim 3, wherein the shielding layer contacts the top surface of the second reflective portion.

6. The display device of claim 3, further comprising a light-shielding portion on the bank; and a color filter at least partially defined by the light-shielding portion to overlap the color conversion layer in the thickness direction,
wherein the shielding layer is spaced apart from the second reflective portion in the thickness direction and is between the second reflective portion and the light-shielding portion.

7. The display device of claim 2, further comprising:
a lower substrate on which the pixel defining layer and the light-emitting portion are arranged;
an upper substrate;
a color filter on a bottom surface of the upper substrate; and
a light-shielding portion at least partially defining a side of the color filter and including a first light-shielding portion and a second light-shielding portion that are sequentially stacked from the bottom surface of the upper substrate.

8. The display device of claim 7, wherein the first light-shielding portion protrudes from the second light-shielding portion and completely covers the second reflective portion in a thickness direction.

9. The display device of claim 2, further comprising a non-colored shielding layer that completely covers a top surface of the second reflective portion.

10. The display device of claim 9, wherein the non-colored shielding layer comprises molybdenum (Mo) or an oxide thereof.

11. The display device of claim 2, further comprising a capping layer between of the second reflective portion and the top surface of the color conversion layer.

12. The display device of claim 2, wherein the first reflective portion contacts sidewalls of the bank and the color conversion layer.

13. The display device of claim 1, wherein the second separation distance is greater than the first separation distance.

14. The display device of claim 1, wherein a boundary of the reflective layer is located between a boundary of the color conversion region and a boundary of the light-emitting region in the plan view.

15. A display device, comprising:
a pixel defining layer defining a light-emitting region;
a light-emitting portion formed within the light-emitting region;
a bank on the pixel defining layer to define a color conversion region that covers the light-emitting region in a plan view and forms a pixel region together with the light-emitting region;
a color conversion layer in the color conversion region; and
a reflective layer on a peripheral portion of a top surface of the color conversion layer,
wherein the pixel region has a major axis side and a minor axis side, and a separation distance between boundaries of the reflective layer and the light-emitting region in a minor axis direction at the major axis side is greater than a separation distance between boundaries of the reflective layer and the light-emitting region in a major axis direction at the minor axis side.

16. The display device according to claim 15, wherein a spacing distance between the color conversion region and the light-emitting region in the plan view is constant throughout the pixel region.

17. A method of manufacturing a display device, comprising:
forming a color filter on an upper substrate;
forming a capping layer on the color filter;
forming a bank that forms a first opening on the capping layer;
forming a reflective layer in contact with a surface of the bank and a bottom surface of the first opening;
partially etching a portion of the reflective layer formed on the bottom surface of the first opening to form a reflective portion including an edge portion formed on a periphery of the bottom surface of the first opening;
forming a color conversion layer filling the first opening on the reflective portion and the capping layer to form an upper structure including the upper substrate, the color filter and the color conversion layer; and
laminating the upper structure with a lower structure including a light-emitting portion and a lower substrate.

18. The method of claim 17, wherein forming the reflective portion comprises variably forming a distance between the edge portion and a sidewall of the bank.

19. An electronic device, comprising:
the display device of claim 1;
a housing supporting the display device; and
a window structure providing a screen of the display device.

20. The electronic device of claim 19, wherein the electronic device is one of a flat panel display, a curved display, a computer monitor, a medical monitor, a television, a billboard, an indoor or outdoor lighting, a signal light, a head-up display, a transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a virtual or augmented reality display, a vehicle, a video wall, a theater or stadium screen, or a phototherapy device.
